(19) United States
(12) Patent Application Publication
(10) Pub. No.: US 2015/0001450 A1
(43) Pub. Date: Jan. 1, 2015

(54) Crystallization of Nanocrystals That Were Formed Using Colloidal Chemistry

(71) Applicant: Evident Technologies, Troy, NY (US)

(72) Inventors: Clinton T. Ballinger, Burnt Hills, NY (US); Adam Z. Peng, Schenectady, NY (US); Gregg Bosak, Hoosick Falls, NY (US); Bed Poudel, Newtonville, MA (US); Susanthri Perera, Cohoes, NY (US)

(21) Appl. No.: 14/317,679

(22) Filed: Jun. 27, 2014

Related U.S. Application Data
(60) Provisional application No. 61/840,631, filed on Jun. 28, 2013.

(51) Int. Cl. C30B 7/00; B02C 23/00; B02C 15/00

(52) U.S. Cl. CPC C30B 7/00; B02C 15/00; B02C 23/00
USPC 252/500; 117/68; 241/25

(57) ABSTRACT

Disclosed herein is a method of crystallizing a semiconductor nanocrystal population including suspending the semiconductor nanocrystal population in a high boiling point solvent to form a solution and heating the solution to a temperature of approximately 100° C. to approximately 400° C. Further disclosed is a method of crystallizing a semiconductor nanocrystal population including drying the semiconductor nanocrystal population into a powder, placing the powder into a ball mill, and ball milling the powder for a duration of time.

### CROSS-REFERENCE TO RELATED APPLICATIONS

This application claims the benefit of co-pending U.S. Provisional Application Ser. No. 61/840,631, filed 28 Jun. 2013, which is hereby incorporated by reference herein.

### FIELD OF THE INVENTION

Embodiments of the present invention relate generally to methods of crystallizing colloidally suspended nanocrystals via heating and in an alternative embodiment, ball milling methodologies.

### BACKGROUND OF THE INVENTION

Semiconductor nanocrystals, or quantum dots, can be produced in a variety of ways. When produced in a colloidal suspension, they are often formed as a connected atomic species. However, in some instances, they do not form a perfect lattice, and are therefore not considered to be completely crystalline. This is an artifact of the previous methods utilized in colloidal synthesis. For instance, in previous attempts at colloidal growth and suspension of semiconductor nanocrystals, the different atomic species present in the solution can move throughout the solvent. In some cases, these atomic species will attach to the nanocrystal surface during formation of the nanocrystal. In doing so, the bonding site may not be ideal for forming a well-structured lattice that is characteristic of semiconductor nanocrystals.

This lattice structure, however, is an important aspect of the characteristics of semiconductor nanocrystals. The electronic band structure of a semiconductor nanocrystal is largely affected by the lattice structure. Further, flaws in the lattice structure more easily allow impurity atoms within the semiconductor nanocrystal due to the lack of proper ordering within the structure.

### BRIEF DESCRIPTION OF THE INVENTION

Embodiments of the invention disclosed herein may include a method of crystallizing a semiconductor nanocrystal population comprising: suspending the semiconductor nanocrystal population in a high boiling point solvent to form a solution; and heating the solution to a temperature of approximately 100° C. to approximately 400° C.

Embodiments of the invention may also include a crystallized semiconductor nanocrystal population made by a method, the method comprising: suspending a semiconductor nanocrystal population in a high boiling point solvent to form a solution; and heating the solution to a temperature of approximately 100° C. to approximately 400° C.

Embodiments of the invention may also include a method of crystallizing a semiconductor nanocrystal population comprising: drying the semiconductor nanocrystal population into a powder; placing the powder into a ball mill; and ball milling the powder for a duration of time.

Embodiments of the invention may also include a crystallized semiconductor nanocrystal population made by a method, the method comprising: drying a semiconductor nanocrystal population into a powder; placing the powder into a ball mill; and ball milling the powder for a duration of time.

### BRIEF DESCRIPTION OF THE DRAWINGS

FIG. 1 shows an example flow diagram according to embodiments of the invention.

FIG. 2 shows an example flow diagram according to other embodiments of the invention.

### DETAILED DESCRIPTION OF THE INVENTION

Embodiments of the present invention include methods of crystallizing semiconductor nanocrystals more effectively, creating a more consistent lattice structure. Previous attempts have utilized heat in an effort to give sufficient energy to the lattice to enable the atoms to migrate and shift into a more consistent crystalline lattice. To some extent, this is similar to annealing processes, wherein thermal energy is used to shift the atoms into a more crystalline shape. In previous attempts to ‘anneal’ into a crystalline structure, heat was typically applied to the powder form of the semiconductor nanocrystals. However, when heat is applied to the powder form, semiconductor nanocrystals typically grow beyond the desired size as atoms near to the nanocrystals, including those from neighboring nanocrystals, tend to bond together. Since semiconductor nanocrystals' properties are largely based on the size of the nanocrystal, this can cause severe problems in trying to tune the crystallized nanocrystals.

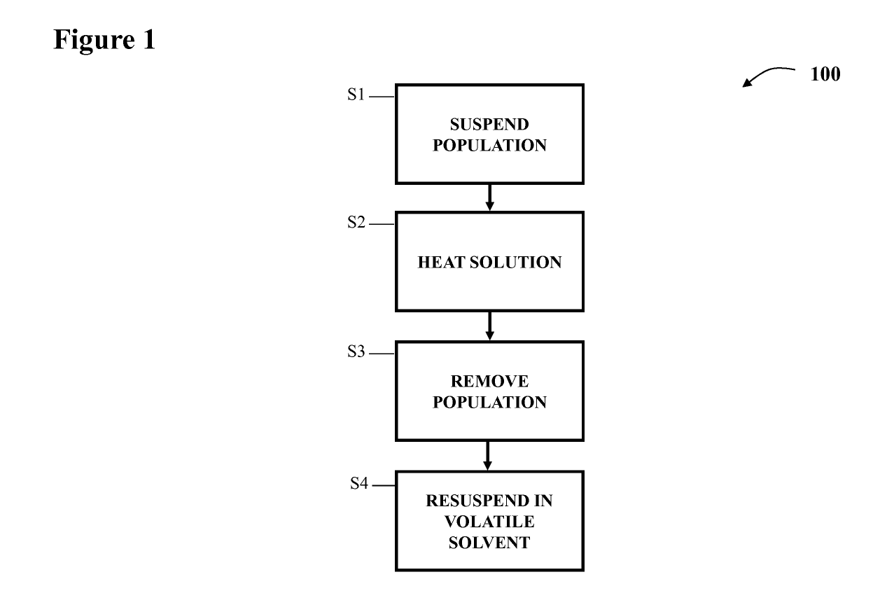

In one embodiment, as illustrated in FIG. 1, a method 100 of crystallizing a semiconductor nanocrystal population can include suspending the semiconductor nanocrystal population in a high boiling point solvent to form a solution (S1). Semiconductor nanocrystals, which may include quantum dots, are known in the art. This method can be used on any now known or later developed semiconductor nanocrystal, including a single population of the same material within a small size distribution, or on a combination of either different material systems or different sizes, or some combination thereof. The semiconductor nanocrystals may be provided in any number of ways. For instance, they may be purchased commercially or synthesized by traditional methods prior to utilizing the disclosed methods.

In many cases, the semiconductor nanocrystal population may be provided already suspended in a volatile solvent with a relatively low boiling point, as many applications require such a suspension. However, these solutions have too low of a boiling point to effectively heat the solution to the point of crystallization. For instance, hydrazine is one example of such a solvent. Hydrazine has a boiling point of approximately 114° C. This is too low for most desired annealing processes. Accordingly, the semiconductor nanocrystal population can be suspended in a relatively higher boiling point solvent. This solvent may include tri-octyl phosphine (TOP), oleic acid, n-methylformamide, any other formamide derivative, and a variety of organic solvents. These solvents are illustrative, but not meant to be limiting. In some instances, the solvent should have a boiling point of approximately 100° C. or more. In further embodiments, the boiling point may be at least approximately 250° C.

Once the semiconductor nanocrystal has been suspended in a high boiling point solvent, the resulting solution may be heated to a temperature capable of crystallizing the population (S2). In some embodiments, this temperature may include a range of approximately 100° C. to approximately 400° C. In a further embodiment, the range can include approximately 250° C. to approximately 400° C. This temperature range is the reason that the above described lower boiling point solvents may not be compatible with the methods disclosed herein. However, in a further embodiment, a lower boiling point solvent such as hydrazine may be used for this heating step; however, the solution would need to be in a pressurized environment in order to avoid boiling of the solvent.

This method has multiple advantages over prior methods. For example, when the nanocrystals are heated in close proximity to one another at a high enough temperature, the atoms have enough energy to move around and reposition into a well formed crystalline lattice structure, without the typical downfall of grain growth that occurs by heating the powder. In a further embodiment, the solution containing the semiconductor nanocrystal population may benefit from being more dilute. A dilute solution of nanocrystals can add to the advantages of this method by further separating individual nanocrystals from one another, further reducing the possibility of grain growth between nanocrystals. Further, during the increase in energy from heating in solution and the more ordered structure of the resulting lattice, impurity atoms tend to migrate towards the surface of the nanocrystals and may even disassociate from the nanocrystal and be driven into solution, resulting in a more pure semiconductor nanocrystal of the desired material system.

Following heating of the solution, in one embodiment the semiconductor nanocrystal population may be removed from the solution (S3). This can eliminate any impurities left behind in the solution, as well as provide a more useful medium for the nanocrystals. Following removal from the high boiling point solution, the semiconductor nanocrystal population may be resuspended in a volatile solvent (S4). As one example, the volatile solvent may include hydrazine. Upon suspension in the volatile solvent, a crystallized population of semiconductor nanocrystals is provided. This population of crystallized semiconductor nanocrystals is also provided in a solvent which may be useful for many applications. A further embodiment includes the crystallized semiconductor nanocrystal population made according to the above disclosed method.

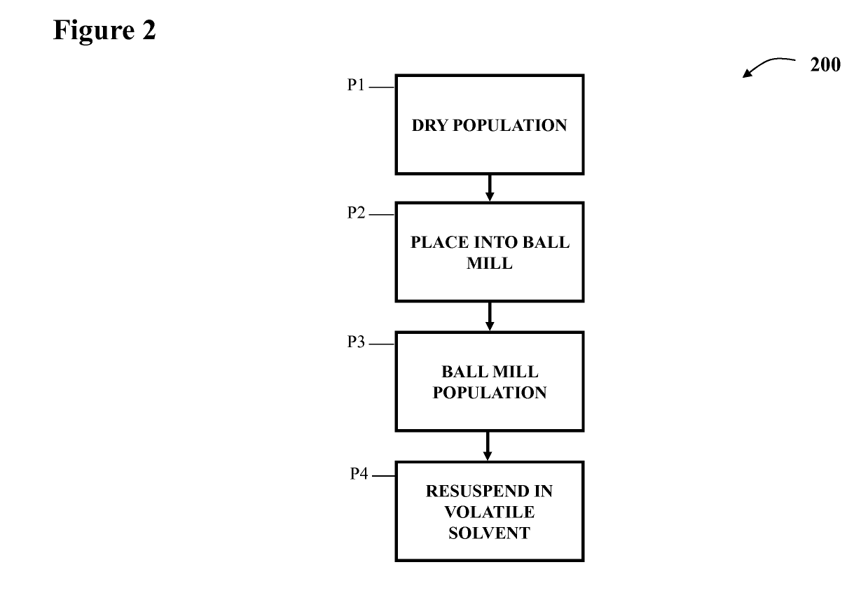

In an alternative embodiment, as illustrated in FIG. 2, a population of semiconductor nanocrystals may be crystallized by a method 200 including drying any of the above disclosed semiconductor nanocrystal populations into a powder (P1). This may be achieved by evaporating the solvent, precipitating the nanocrystals by centrifugation or any other known method, or the like. The powder may further be dried under heat, vacuum, inert over-pressure, or some combination thereof in order to thoroughly dry the nanocrystal powder to desired dryness. Once dried, the powder may be placed into a ball mill (P2). The ball mill may include any now known or later developed ball mill capable of milling a powder. The powder may then be ball milled for a duration of time (P3). The amount of time depends on a number of parameters. For instance, the size of the nanocrystals, the chemical makeup of the nanocrystals, the desired level or type of crystalinity and lattice structure, the starting level of crystalinity, or the previously used synthesis method can all affect the length of time necessary for ball milling. Accordingly, the powder may be ball milled for approximately one hour up to approximately 24 hours. In some embodiments, the powder may be ball milled for more than 24 hours.

In order to determine how long to ball mill the powder, which uses kinetic energy to crystallize the powder, one can measure the level of crystallization at predetermined periods throughout the milling process. For instance, differential scanning calorimetry (DSC) can be performed to measure the level of crystalinity. Using techniques such as DSC, the crystallization of the starting powder can be measured in order to estimate the length of time needed to ball mill. Further, the milled powder can be tested periodically during milling to determine if the desired crystallization has yet occurred, stopping the process if it has or continuing the ball milling if not. Once the powder has been ball milled to the desired specifications, the crystallized nanocrystals may be resuspended in a volatile solvent (P4), for instance hydrazine. In a further embodiment, a crystallized semiconductor nanocrystal population made by the above disclosed methods is included.

The methods disclosed herein can be useful for any number of types of nanocrystals, including all types of semiconducting nanocrystals and quantum dots.

The foregoing description of various aspects of the invention has been presented for the purpose of illustration and description. It is not intended to be exhaustive or to limit the invention to the precise form disclosed, and obviously, many modifications and variations are possible. Such variations and modifications that may be apparent to one skilled in the art are intended to be included within the scope of the present invention as defined by the accompanying claims.

What is claimed:

1. A method of crystallizing a semiconductor nanocrystal population comprising:
suspending the semiconductor nanocrystal population in a high boiling point solvent to form a solution; and
heating the solution to a temperature of approximately 100° C. to approximately 400° C.

2. The method of claim 1, wherein the high boiling point solvent is chosen from a group consisting of: tri-octyl phosphine, oleic acid, n-methylformamide, formamide derivates, and an organic solvent.

3. The method of claim 1, further comprising:
removing the semiconductor nanocrystal population from the solution; and
resuspending the semiconductor nanocrystal population in a volatile solvent.

4. The method of claim 3, wherein the volatile solvent includes hydrazine.

5. A crystallized semiconductor nanocrystal population made by a method, the method comprising:
suspending a semiconductor nanocrystal population in a high boiling point solvent to form a solution; and
heating the solution to a temperature of approximately 100° C. to approximately 400° C.

6. The crystallized semiconductor nanocrystal population of claim 5, wherein the high boiling point solvent is chosen from a group consisting of: tri-octyl phosphine, oleic acid, n-methylformamide, formamide derivates, and an organic solvent.

7. The crystallized semiconductor nanocrystal population of claim 5, the method further comprising:
removing the crystallized semiconductor nanocrystal population from the solution; and
resuspending the crystallized semiconductor nanocrystal population in a volatile solvent.

8. The crystallized semiconductor nanocrystal population of claim 7, wherein the volatile solvent includes hydrazine.

9. A method of crystallizing a semiconductor nanocrystal population comprising:
drying the semiconductor nanocrystal population into a powder;
placing the powder into a ball mill; and
ball milling the powder for a duration of time.

10. The method of claim 9, wherein the duration of time comprises approximately 1 hour to approximately 24 hours.

11. The method of claim 9, wherein the duration of time comprises more than approximately 24 hours.

12. The method of claim 9, the method further comprising:
resuspending the ball milled semiconductor nanocrystal population in a volatile solvent.

13. The method of claim 12, wherein the volatile solvent comprises hydrazine.

14. A crystallized semiconductor nanocrystal population made by a method, the method comprising:
drying a semiconductor nanocrystal population into a powder;
placing the powder into a ball mill; and
ball milling the powder for a duration of time.

15. The crystallized semiconductor nanocrystal population of claim 14, wherein the duration of time comprises approximately 1 hour to approximately 24 hours.

16. The crystallized semiconductor nanocrystal population of claim 14, wherein the duration of time comprises more than approximately 24 hours.

17. The crystallized semiconductor nanocrystal population of claim 14, the method further comprising:
resuspending the ball milled semiconductor nanocrystal population in a volatile solvent.

18. The crystallized semiconductor nanocrystal population of claim 17, wherein the volatile solvent comprises hydrazine.
